(19) United States
(12) Patent Application Publication
(10) Pub. No.: US 2022/0068655 A1
(43) Pub. Date: Mar. 3, 2022

(54) APPARATUS AND METHOD FOR PLANARIZING A SUBSTRATE

(71) Applicant: SK hynix Inc., Gyeonggi-do (KR)

(72) Inventor: Jae Hee SIM, Gyeonggi-do (KR)

(21) Appl. No.: 17/206,528

(22) Filed: Mar. 19, 2021

(30) Foreign Application Priority Data
Sep. 2, 2020 (KR) 10-2020-0111446

(51) Int. Cl. H01L 21/3105; H01L 21/67

(52) U.S. Cl. CPC H01L 21/31051; H01L 21/67259

(57) ABSTRACT

An apparatus for planarizing a substrate may include a supporting plate, an injection mechanism and a controller. The supporting plate may be configured to receive the substrate including a coating layer formed on the substrate before a hardening process. The supporting plate may have at least one of a function for controlling a temperature of the substrate, a function for rotating the substrate and a function for vibrating the substrate. The injection mechanism may inject a gas having a set temperature and a set pressure to the coating layer of the substrate to horizontally planarize the coating layer. The controller may control a movement, a temperature and a pressure of the injection mechanism, and the temperature control, the rotation control and the vibration control of the supporting plate.

### CROSS-REFERENCES TO RELATED APPLICATION

The present application claims priority under 35 U.S.C. § 119(a) to Korean application number 10-2020-0111446, filed on Sep. 2, 2020, which is incorporated herein by reference in its entirety.

### BACKGROUND

### 1. Technical Field

Various embodiments may generally relate to an apparatus and a method for planarizing a substrate.

### 2. Related Art

In order to effectively perform a plurality of semiconductor fabrication processes, flatness of a wafer is an important factor.

Generally, chemical mechanical polishing (CMP) may be used for obtaining a flat wafer. However, because a cleaning process is typically performed together with the CMP process, various additional matters relating to the process and its cost may exist. Further, when a coated material on the wafer is soft, the above-mentioned processes cannot be performed frequently.

Particularly, in order to planarize a material coated on the wafer such as a photoresist (PR), a spin on carbon (SOC), a bottom anti-reflective coating (BARC), a spin-on dielectric (SOD), an underlayer, etc., a relatively harder material may be formed on the material. The coating material may be, for example, a polyimide. The CMP process may then be performed on the material. Thus, the formation of the harder material may be additionally performed.

For example, the SOC may be a carbon-based hard mask. Issues such as a depth of focus (DOF) may be generated due to planarization used before a photo-lithography process. When applying a spacer pattern technology (SPT) mesh process, a non-opened problem due to a step may be generated after a following process.

### SUMMARY

Various embodiments provide an apparatus and a method of planarizing a substrate that is capable of improved planarization including improved planarization capacity.

In various embodiments of the present disclosure, an apparatus for planarizing a substrate may include a supporting plate, an injection mechanism and a controller. The supporting plate may be configured to receive the substrate including a coating layer formed on the substrate before a hardening process. The supporting plate may have at least one of a function for controlling a temperature of the substrate, a function for rotating the substrate and a function for vibrating the substrate. The injection mechanism may inject a gas having a set temperature and a set pressure to the coating layer of the substrate to horizontally planarize the coating layer. The controller may control a movement, a temperature and a pressure of the injection mechanism, and the temperature control, the rotation control and the vibration control of the supporting plate.

In various embodiments of the present disclosure, according to a method of planarizing a substrate, injection conditions including a set temperature and a set pressure of a gas, which may be injected to the substrate, may be determined. The substrate on which a coating layer may be formed before a hardening process may be prepared. A gas having the temperature and the pressure set in accordance with the injection conditions may be injected to the coating layer.

In an embodiment of the present disclosure, an apparatus may include: a supporting plate for receiving a semiconductor substrate, the supporting plate being capable of rotating, and vibrating to impart the rotating and vibrating to the substrate for planarizing a coating layer disposed on the substrate; and an injection mechanism the injection mechanism comprising a plurality of nozzles, wherein the injection mechanism injects a first gas having a first temperature through at least one of the plurality of the nozzles on a first surface of the coating layer, and a second gas having a second temperature through at least another one of the plurality of nozzles on a second surface of the coating layer.

According to various embodiments of the present disclosure, the substrate may be planarized using the gas having the set temperature and the set pressure. Thus, additional processes such as a CMP process, a cleaning process, etc., may be omitted to simplify the planarization process. The coating layer on the substrate may have improved flatness regardless of an operation on the substrate.

Further, a DOF margin of the substrate may be improved to simplify the planarization process.

Furthermore, an open process of a cell or a periphery may also be simplified.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a view illustrating an apparatus for planarizing a substrate in accordance with an embodiment of the present disclosure;

FIG. 2 is a view illustrating a gas nozzle in FIG. 1;

FIG. 3 is a view illustrating an injection mechanism in accordance with an embodiment of the present disclosure;

FIG. 4 is a view illustrating an injection mechanism in accordance with an embodiment of the present disclosure;

FIG. 5 is a view illustrating operations for controlling angles of an injection mechanism in accordance with an embodiment of the present disclosure;

FIG. 6 is a view illustrating operations for controlling angles of an injection mechanism in accordance with an embodiment of the present disclosure;

FIGS. 7 to 12 are views illustrating movements of an injection mechanism and a substrate in accordance with an embodiment of the present disclosure;

FIG. 13 is a view illustrating an apparatus for planarizing a substrate in accordance with an embodiment of the present disclosure;

FIGS. 14 and 15 are views illustrating operations of the planarizing apparatus in FIG. 13; and

FIG. 16 is a flow chart illustrating a method of planarizing a substrate in accordance with an embodiment of the present disclosure.

### DETAILED DESCRIPTION

Various embodiments of the present invention will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention A substrate of an embodiment may include a wafer, not restricted within the wafer.

According to a first aspect of the invention, an apparatus is provided for planarizing a coating layer of a substrate. The apparatus may comprise a supporting plate for receiving the substrate. The supporting plate may be capable of rotating, and vibrating to impart the rotating and vibrating to the substrate for planarizing the coating layer disposed on the substrate.

The apparatus may further include an injection mechanism comprising a plurality of nozzles. The injection mechanism may inject a first gas having a first temperature through at least one of the plurality of the nozzles on a first surface of the coating layer and a second gas having a second temperature through at least another one of the plurality of nozzles on a second surface of the coating layer. The pressures of the first gas and the second gas may also be controlled and may be the same or different. The injection mechanism may further include a plurality of regions corresponding to the plurality of nozzles.

The injection mechanism may also be movable so that its positioning relative to the coating layer top surface may be adjusted. For example, the injection mechanism may be moved towards or away from the top surface of the coating layer to obtain a desirable distance between the nozzles and the top surface prior to injecting the gas. The injection mechanism may be rotatable. Also, the plurality of nozzles may be movable to adjust their orientation relative to the top surface of the coating layer so that an angle of injecting the gas to the top surface may be changed. Each nozzle may be movable independently.

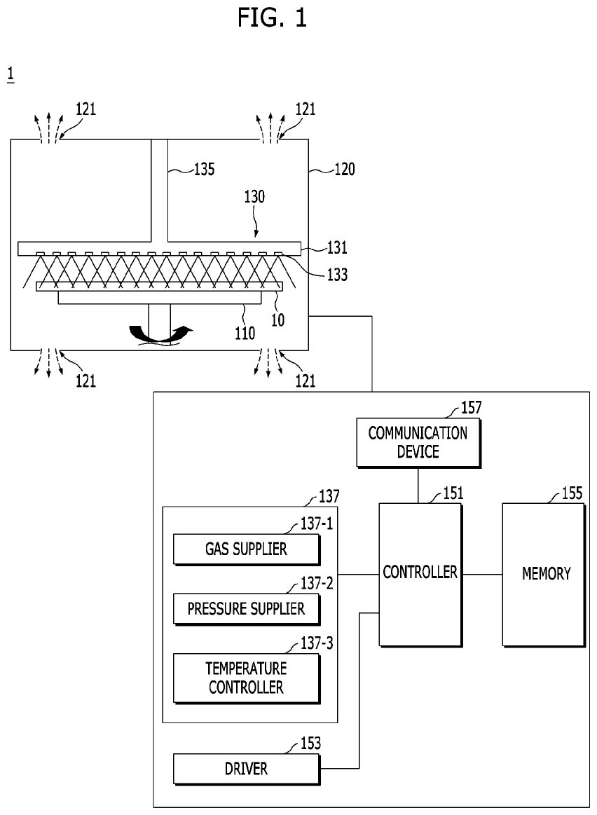

FIG. 1 is a view illustrating an apparatus for planarizing a substrate in accordance with an embodiment of the present disclosure.

Referring to FIG. 1, a planarizing apparatus 1 may include a supporting plate 110, a chamber 120, an injection mechanism 130, a controller 151, a driver 153, a memory 155 and a communication device 157.

The supporting plate 110 may be configured to receive a substrate 10 on which a coating layer may be formed before a hardening process. The supporting plate 110 may have at least one of a function for controlling a temperature of the substrate 10, a function for rotating the substrate 10 and a function for vibrating the substrate 10.

For example, although not depicted in the drawings, the supporting plate 110 may include at least one of a member for controlling a temperature of the substrate 10, a member for rotating the substrate 10, and a member for vibrating the substrate 10. In an embodiment, the supporting plate may include a member for controlling the temperature of the substrate 10, a member for rotating the substrate 10, and a member for vibrating the substrate 10. Such members may be any suitable devices.

For, example, the member for vibrating the substrate 10 may employ an ultrasonic technology, or a mega-sonic technology. These are just examples of suitable technologies and it is noted that the member for vibrating the substrate may not be solely within these specific examples. Other technologies may be used. When the member may include the mega-sonic technology, a vibration may be about 1 Khz to about 10 Mhz, however the vibration is not restricted within a specific vibration range.

The coating layer before the hardening process may be in state before the hardening process for providing the coating layer with a specific hardness after forming the coating layer on the substrate 10 by various manners. In various embodiments, the coating layer before the hardening process may have flowability before hardening the coating layer.

In order to secure the flowability of the coating layer, the coating layer may be heated to a glass transition temperature or the heated coating layer may be cooled. For controlling the temperature of the substrate within a desired range, the supporting plate 110 may heat or cool the substrate 10. Further, the injection mechanism 130 may control the temperature of a gas injected to the coating layer to secure the flowability of the coating layer. The secure the flowability of the coating layer may mean securing a state in which the coating material of the coating layer is not completely hardened to flow.

The coating layer may include a photoresist (PR), a spin-on-carbon (SOC), a bottom anti-reflective coating (BARC), a spin-on dielectric (SOD), a spin-on-glass (SOG), a top anti-reflective coating material (TARC), a multi-function hard mask (MFHM), an immersion top coat, etc., not restricted within a specific material. For example, the coating layer may be a polyimide.

The supporting plate 110 may heat the substrate 10 to melt the coating layer until the coating layer may have the lowermost viscosity. The supporting plate 110 may apply a vibration to the substrate 10 to move the coating layer, thereby planarizing the coating layer. In this case, the gas injection by the injection mechanism 130 may be selectively performed in accordance with needs of a user. That is, according to various embodiments, the coating layer on the substrate 10 may be planarized only by heating and vibrating the coating layer by the supporting plate 110.

The chamber 120 may include elements of the planarizing apparatus 1 for performing the planarization process on the substrate 10.

The chamber 120 may include at least one outlet 121 formed at a wall of the chamber 120 to exhaust byproducts generated in the process. For example, as illustrated in the embodiment of FIG. 1 two outlets may be formed on each of two opposite walls of the chamber 120.

Although not depicted in drawings, an apparatus for inducing the byproducts to the outlet 121 may be employed, and may, for example, be arranged inside the chamber 120.

The injection mechanism 130 may inject the gas having a set temperature and a set pressure to the coating layer on the substrate 10 to horizontally planarize the coating layer. For example, the gas may include air, N₂, etc., and is not restricted within a specific material.

Particularly, the injection mechanism 130 may include a body plate 131, a gas nozzle 133, a gas line 135 and an injector 137.

The body plate 131 may be combined to be in fluid communication with the gas nozzle 133 to provide the gas nozzle 133 with the gas having the set temperature and the set pressure. The gas may include a material only for allowing the flow of the coating layer, which may not generate a physical change and a chemical change of the coating layer. For example, the gas may include air, N₂, etc., and is not restricted within a specific material.

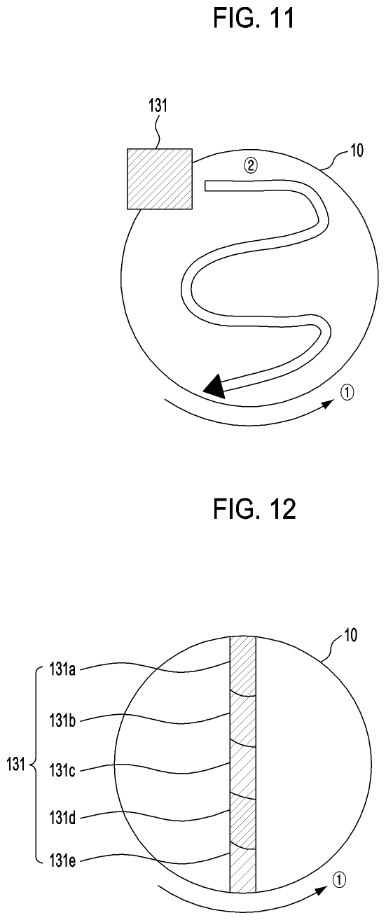

Referring to FIGS. 7 to 8, the body plate 131 may have a first rectangular shape having a length in a first direction equal to a diameter of the substrate 10.

Referring to FIG. 10, the body plate 131 may have a second rectangular shape having a length in a first direction equal to a radius of the substrate 10.

Referring to FIG. 11, the body plate 131 may have a third rectangular shape smaller than the second shape, for example, having a length in the first direction less than or equal to the radius of the substrate 10.

The shapes of the body plate 131 may not be restricted within the first to third shapes. The shapes of the body plate 131 may be changed in accordance with requirements of the user.

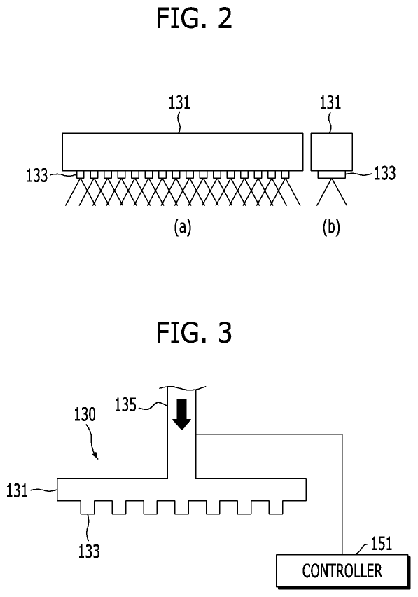

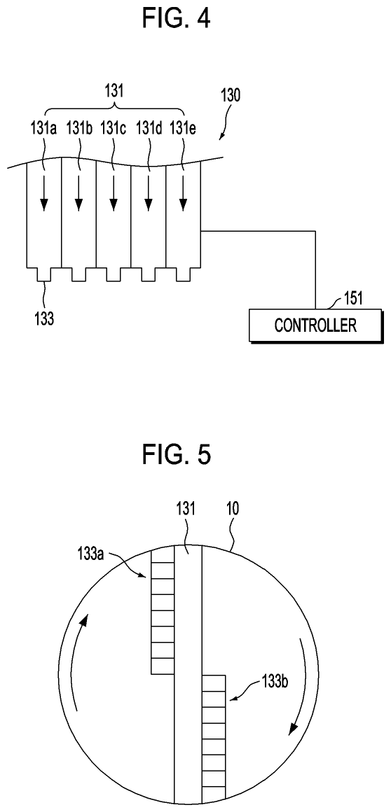

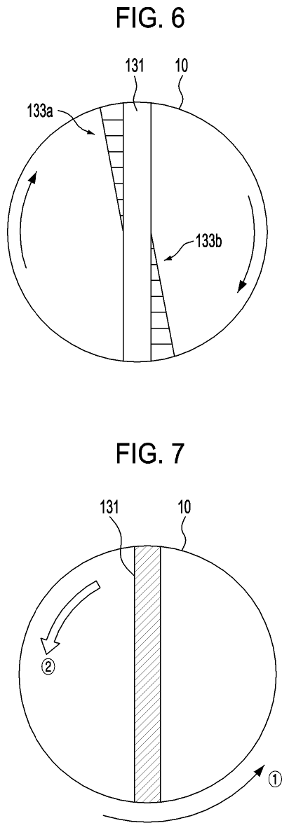

FIG. 2 is a view illustrating a gas nozzle in FIG. 1, FIG. 3 is a view illustrating an injection mechanism in accordance with an embodiment of the present disclosure, and FIG. 4 is a view illustrating an injection mechanism in accordance with an embodiment of the present disclosure.

Referring to FIG. 2, the gas nozzle 133 may include a protrusion type nozzle including a plurality of protruded nozzles. Alternatively, referring to FIG. 1, the gas nozzle 133 may include a slit type nozzle including injection holes. The gas nozzle 133 may include the protrusion type nozzle or the slit type nozzle. The shape of the gas nozzle 133 may be changed in accordance with the user.

Further, the shape of the gas nozzle 133 may be changed in accordance with the user, and is not restricted to the protrusion type or the slit type.

The gas nozzle 133 may be radially arranged at the body plate 131. However, the gas nozzle 133 may have various arrangements in accordance with requirements of the user.

Referring to FIG. 3, the body plate 131 may be a single region connected to the nozzles of the gas nozzle 133. In this case, the gas having the same temperature and the same pressure may be supplied to the nozzles through the gas line 135.

Referring to FIG. 4, the body plate 131 may include a plurality of regions 131a, 131b, 131c, 131d and 131e separated from each other with each region being in fluid communication to a corresponding one of the nozzles of the gas nozzle 133, respectively. In this case, the body plate 131 may be integrally formed with the gas line 135 to perform the function of the gas line 135. The gas having the same temperature and the same pressure or a different temperature and a different pressure may be supplied through the regions 131a, 131b, 131c, 131d and 131e of the body plate 131.

The gas nozzle 133 may inject the gas having the set temperature and the set pressure to the coating layer on the substrate 10.

As shown in FIG. 2, when the gas nozzle 133 may include the protrusion type nozzle, each of the nozzles may have an independently changeable gas injection angle. In FIG. 2, (a) may represent the body plate 131 and the gas nozzle 133 along a first direction, for example, a first side surface, and (b) may represent the body plate 131 and the gas nozzle 133 along a second direction substantially perpendicular to the first direction, for example, a second side surface substantially perpendicular to the first side surface.

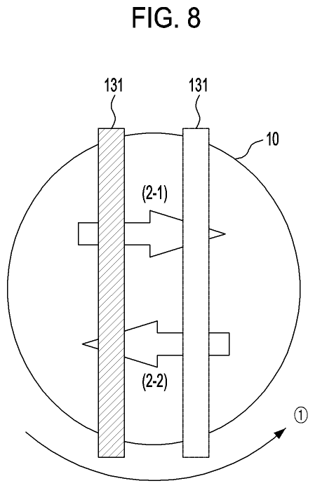

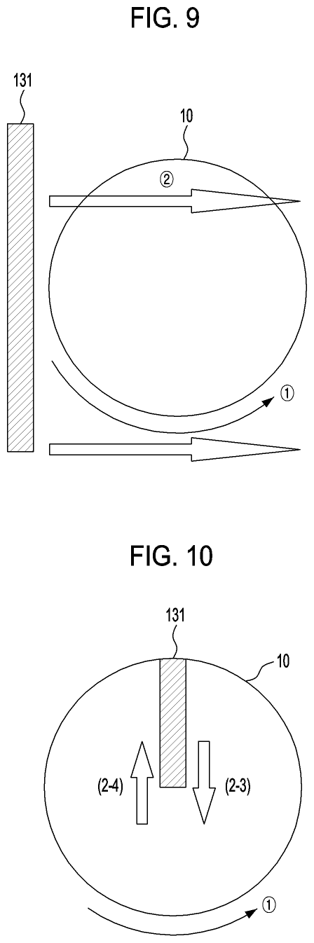

FIG. 5 is a view illustrating operations for controlling angles of an injection mechanism in accordance with an embodiment of the present disclosure, and FIG. 6 is a view illustrating operations for controlling angles of an injection mechanism in accordance with an embodiment of the present disclosure.

Referring to FIG. 5, the nozzles of the gas nozzle 133 may include a first group of nozzles 133a and a second group of nozzles 133b. The first group of the nozzles 133a may be connected to a first surface of the body plate 131. The second group of the nozzles 133b may be connected to a second surface of the body plate 131 opposite to the first surface. Particularly, the first group of the nozzles 133a may be arranged on a half portion of the first surface in the body plate 131 with respect to a center point of the body plate 131. The second group of the nozzles 133b may be arranged on a half portion of the second surface in the body plate 131 with respect to the center point of the body plate 131. The half portion of the first surface in the body plate 131 on which the first group of the nozzles 133a may be arranged may be symmetrical with the half portion of the second surface in the body plate 131 on which the second group of the nozzles 133b may be arranged.

Further, the first group of the nozzles 133a and the second group of the nozzles 133b may have inclined angles to be oriented toward a direction opposite to a rotation direction of the substrate 10. In this case, an area may be increased by an angular velocity of the substrate 10 to increase a pressure of the gas.

Referring to FIG. 6, the nozzles of the gas nozzle 133 may include a first group of nozzles 133a and a second group of nozzles 133b. The first group of the nozzles 133a may be connected to a first surface of the body plate 131. The second group of the nozzles 133b may be connected to a second surface of the body plate 131 opposite to the first surface. Particularly, the first group of the nozzles 133a may be arranged on a half portion of the first surface in the body plate 131 with respect to a center point of the body plate 131. The second group of the nozzles 133b may be arranged on a half portion of the second surface in the body plate 131 with respect to the center point of the body plate 131. The half portion of the first surface in the body plate 131 on which the first group of the nozzles 133a may be arranged may be symmetrical with the half portion of the second surface in the body plate 131 on which the second group of the nozzles 133b may be arranged.

Further, the first group of the nozzles 133a and the second group of the nozzles 133b may have inclined angles to be oriented toward a direction opposite to a rotation direction of the substrate 10. Particularly, the first and second groups of the nozzles 133a and 133b may have gradually increasing inclined angles from the center point to an edge portion in the body plate 131.

Although not depicted in drawings, the gas line 135 may be connected between the injector 137 and the body plate 131 to supply the gas having the set temperature and the set pressure to the body plate 131. Alternatively, the gas line 135 may be omitted in accordance with requirements of the user. Further, the gas line 135 may have other configurations.

The injector 137 may be connected to the body plate 131 to supply the gas having the set temperature and the set pressure to the body plate 131.

The injector 137 may include a gas supplier 137-1, a pressure supplier 137-2 and a temperature controller 137-3. The gas supplier 137-1 may be configured to supply the set gas. The pressure supplier 137-2 may be configured to supply the gas as determined by the controller 151. The temperature controller 137-3 may be configured to control the set temperature.

The injector 137 may provide the body plate 131 with the gas having the same temperature and the same pressure. Alternatively, the injector 137 may provide the body plate 131 with the gas having the different temperatures and the different pressures through the regions 131a, 131b, 131c, 131d and 131e of the body plate 131 so that the gas having the different temperatures and the different pressures may be injected through the nozzles.

For example, when a pattern is formed on the substrate 10, the injector 137 may provide a region among the plurality of the regions of the body plate 131, which may correspond to an edge region of the substrate 10, with a pressure higher than a pressure applied to a region among the plurality of the regions of the body plate 131, which may correspond to a central region of the substrate 10, by the controller 151.

In contrast, when the substrate 10 has a flat upper surface, the injector 137 may provide the region among the plurality of the regions of the body plate 131, which may correspond to the central region of the substrate 10, with a pressure higher than a pressure applied to the region among the plurality of the regions of the body plate 131, which may correspond to the edge region of the substrate 10, by the controller 151.

The injector 137 may provide or not provide each of the regions of the body plate 131 with the gas having the set temperature and the set pressure by the controller 151.

For example, the injector 137 may provide each of the regions 131a, 131b, 131c, 131d and 131e of the body plate 131 with the gas having the set temperature and the set pressure, or stop the supplying of the gas. That is, the injector 137 may individually control on/off of the temperature control and the gas supply with respect to the regions 131a, 131b, 131c, 131d and 131e.

The injector 137 may include an amplifier configured to control the pressure.

The controller 151 may be configured to control the movement, the temperature and the pressure of the injection mechanism 130 and the temperature, the vibration and the rotation of the supporting plate 110.

The controller 151 may determine the temperature and the pressure of the gas in accordance with at least one of a material of the coating layer, a viscous force of the coating layer, a glass transition temperature of the coating layer, a threshold temperature and a threshold pressure applicable to the gas nozzle and the regions of the substrate 10. Further, the controller 151 may control the injector 137 to inject the gas having a determined temperature and a determined pressure.

For example, the coating layer on the substrate may have different hardened degrees by the regions. Further, the gas may have different injection intensities by the regions under the same pressure. Thus, the controller 151 may determine different pressures of the gas applied to the regions based on the above-mentioned stages of the regions of the substrate 10.

Additionally, the controller 151 may control the temperature of the supporting plate 110 as well as the gas in accordance with the glass transition temperature of the coating layer.

For example, the controller 151 may heat or cool the coating layer by controlling the temperature of the supporting plate 110 and the temperature of the injected gas to control the flowing of the coating layer.

FIGS. 7 to 12 are views illustrating movements of an injection mechanism and a substrate in accordance with example embodiments.

Referring to FIG. 7, the driver 153 may rotate the body plate 131 in a direction \textcircled{2} by the controller 151. The driver 153 may rotate the substrate 10 in a direction \textcircled{1} or not rotate the substrate 10.

As shown in FIG. 12, when the body plate 131 has the regions 131a, 131b, the controller 151 may provide the central portion of the body plate 131 with the gas having a pressure higher than a pressure of the gas applied to other portions of the body plate 131. When the body plate 131 may be rotated, the central portion of the body plate 131 may not be moved compared to the edge portion of the body plate 131. Thus, the gas having the uniform pressure may be applied to the substrate 10.

As shown in FIG. 12, when the body plate 131 may have the regions 131a, 131b, the controller 151 may set the different pressures and the different temperatures of the gas by the regions or control the individual on/off to induce a uniform flow of the coating layer on the substrate 10.

Referring to FIG. 8, after the driver 153 moves the body plate 131 in a (2-1) direction, the body plate 131 may be moved in a (2-2) direction after a reference time. In this case, the gas having the uniform temperature and the uniform pressure may be applied to the regions of the substrate 10. Here, the driver 153 may rotate or not rotate the substrate 10 in the direction \textcircled{1}.

Referring to FIG. 10, after the driver 153 moves the body plate 131 in a (2-3) direction, the body plate 131 may be moved in a (2-4) direction after a reference time. Here, the driver 153 may rotate or not rotate the substrate 10 in the direction \textcircled{1}.

Referring to FIG. 9, the driver 153 may move the body plate 131 from one end of the substrate 10 to the other end of the substrate 10 in the direction \textcircled{2} by the controller 151. For example, the driver 153 may move the body plate 131 to scan the whole upper surface of the substrate 10.

Referring to FIG. 11, the driver 153 may move the body plate 131 along a predetermined path by the controller 151.

Referring to FIGS. 7 to 12, the driver 153 may rotate the supporting plate 110 by the controller 151 to rotate the substrate 10.

The memory 155 may be configured to store information with respect to the planarizing apparatus 1. For example, the memory 155 may include information with respect to an identification of the substrate 10, the material of the coating layer on the substrate 10, the glass transition temperature of the coating layer, the pressure, the types of the gas, planarization results, viscosity of the substrate 10 by the regions, etc.

The communication device 157 may be configured to communicate information between the planarizing apparatus 1 and an external device, for example, the user's terminal, a main server, etc.

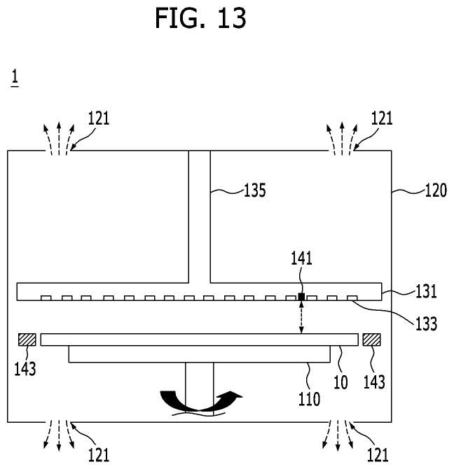

FIG. 13 is a view illustrating an apparatus for planarizing a substrate in accordance with an embodiment of the present disclosure.

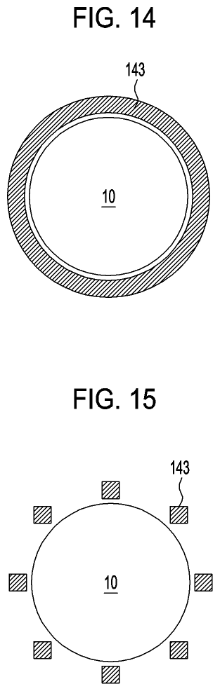

Hereinafter, operations of the planarizing apparatus in FIG. 13 may be illustrated with reference to FIGS. 14 and 15. Further, the same reference numerals may refer to the same elements and any further illustrations with respect to the same element may be omitted herein for brevity.

Referring to FIG. 13, the planarizing apparatus 1 may include the supporting plate 110, the chamber 120, the injection mechanism 130, the controller 151, the driver 153, the memory 155 and the communication device 157.

Additionally, the planarizing apparatus 1 may further include a first detection sensor 141 and a second detection sensor 143.

The first detection sensor 141 may be arranged on at least one of a region of the body plate 131 and a region of the gas nozzle 133 fronting the substrate 10 to detect a distance between the first direction sensor 141 and the substrate 10 on the supporting plate 10. The first detection sensor 141 may communicate with the controller 151 and may provide the controller 151 with the detected distance. In an embodiment, the sensor 141 and the controller 151 may communicate via a wire connection. The sensor 141 and the controller 151 may communicate via a wireless connection.

The controller 151 may control an ascending or a descending of the body plate 131 or the on/off operations of the gas injection based on the distance transmitted from the first detection sensor 141.

The second detection sensor 143 may be arranged spaced apart from an outer surface of the substrate 10 by a distance to detect the temperature and the pressure of the gas injected from the gas nozzle 133. The second detection sensor 143 may provide the controller 151 with the detected temperature and pressure.

The controller 151 may stop the gas supply to a nozzle among the nozzles of the gas nozzle 133 corresponding to detection position information of the second detection sensor 143 based on the temperature and the pressure of the gas detected by the second detection sensor 143 and the detection position information of the second detection sensor 143.

Identification information may be assigned to the nozzles and the second detection sensor 143. The identification information may be stored in the memory 155.

Referring to FIG. 14, the second detection sensor 143 may be spaced apart from the outer surface of the substrate 10. The second detection sensor 142 may be configured to surround the outer surface of the substrate 10.

Alternatively, referring to FIG. 15, the second detection sensor 143 may be spaced apart from the outer surface of the substrate 10, but may be configured to partially surround the outer surface of the substrate 10. In other words, according to the embodiment of FIG. 15, the second detection sensor 143 may include a plurality of spaced apart sensors arranged circumferentially around the substrate 10.

Generally, the shape of the second detection sensor 143 may not be restricted within the shapes in FIGS. 14 and 15 but, rather, the shape of the second detection sensor 143 may be changed in accordance with requirements of the user.

The gas injected from the gas nozzle 133 may be used for planarizing the substrate 10. When the gas is injected to other parts besides the substrate 10, unnecessary byproducts, which may have bad influence on semiconductor fabrication processes, may be generated. In an embodiment, the second detection sensor 142 may be used for preventing the gas from the gas nozzle 133 from being injected to the other parts besides the substrate 10.

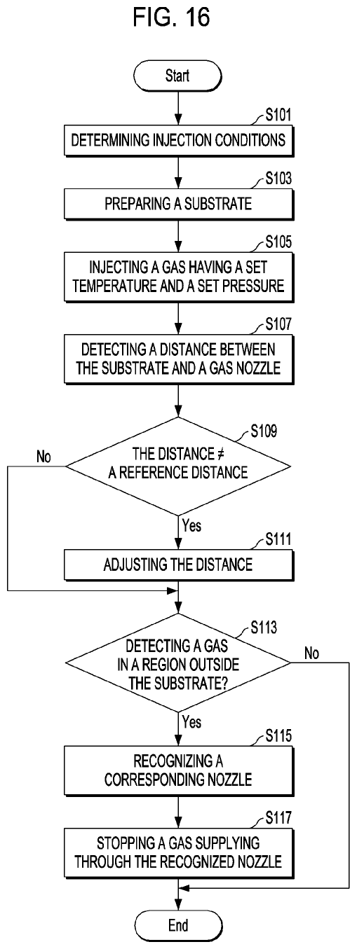

FIG. 16 is a flow chart illustrating a method of planarizing a substrate in accordance with an embodiment of the present disclosure.

Referring to FIG. 16, in operation S101, the planarizing apparatus 1 may determine the injection conditions such as the pressure of the gas applied to the substrate 10.

The gas having the temperature and the pressure set by the injection conditions may be injected through the gas nozzle 133.

The planarizing apparatus 1 may determine the temperature and the pressure of the gas based on at least one of a material of the coating layer, a viscous force of the coating layer, a glass transition temperature of the coating layer, a threshold temperature and a threshold pressure applicable to the gas nozzle and the regions of the substrate 10.

In operation S103, the planarizing apparatus 1 may prepare the substrate 10 on which the coating layer may be formed before the hardening process.

Referring to FIG. 1, the planarizing apparatus 1 may place the substrate 10 on the supporting plate 110.

The planarizing apparatus 1 may heat or cool the supporting plate 110 to control the temperature of the substrate 10, thereby controlling the flowability of the coating layer within a desired range.

Further, the planarizing apparatus 1 may rotate the substrate 10 or apply the vibration to the substrate 10 as may be needed.

In operation S105, the planarizing apparatus 1 may inject the gas having the temperature and the pressure set based on the injection conditions to the coating layer on the substrate 10.

The planarizing apparatus 1 may inject the gas to the upper surface of the substrate 10 with rotating the gas, with changing the injection direction in any of the first to fourth directions based on a predetermined time, with moving from one end to the other end in the substrate 10, or with moving along a predetermined path.

The operation S105 may further include rotating the substrate 10 while injecting the gas having the set temperature and the set pressure, or applying vibration to the substrate 10. For example, the planarizing apparatus 1 may rotate the supporting plate 110 using the driver 153 to rotate the substrate 10.

Further, in injecting the gas, the planarizing apparatus 1 may inject the gas having the different temperatures and the different pressures or the gas having the same temperature and the same pressure from the nozzles. The gas having the set temperature and the set pressure may be injected through the gas nozzle 133.

Further, in injecting the gas, the planarizing apparatus 1 may provide the gas having the set temperature and the set pressure through each of the nozzles, or not provide the gas. That is, a specific nozzle among the nozzles may inject the gas while other nozzles may not inject the gas.

Furthermore, in injecting the gas, the planarizing apparatus 1 may individually change the injection angles of the nozzles.

In operation S107, the planarizing apparatus 1 may detect the distance between the gas nozzle 133 and the substrate 10.

The gas having the set temperature and the set pressure may be injected through the gas nozzle 133.

Referring to FIG. 13, the planarizing apparatus 1 may include the first detection sensor 141. The first detection sensor 141 may be arranged on the region fronting the substrate 10 to detect a distance between the first direction sensor 141 and the substrate 10 on the supporting plate 10. The first detection sensor 141 may provide the controller 151 with the detected distance.

The first detection sensor 141 may be arranged on the region of the body plate 131 as well as on the region of the gas nozzle 133 to detect the distance between the body plate 131 and the substrate 10 on the supporting plate 10.

In operations S109 and S111, the planarizing apparatus 1 may compare the detected distance with a reference distance and if the detected distance differs from the reference distance the planarizing apparatus may then adjust the distance between the gas nozzle 133 and the substrate 10 as may be needed in order to obtain the reference distance between the body plate 131 and the substrate 10 positioned on the supporting plate 10. When the detected distance is the same as the reference distance then the operation S113 is performed.

In operation S113, the planarizing apparatus 1 may identify whether the gas may be detected in the region outside the substrate 10 or not.

The gas having the set temperature and the set pressure may be injected through the gas nozzle 133.

When the gas is detected in the region outside the substrate 10, in operation S115, the planarizing apparatus 1 may recognize a nozzle corresponding to the detected region.

In operation S117, the planarizing apparatus 1 may stop the gas supply through the detected nozzle. Thus, the planarizing apparatus 1 may include the second detection sensor 143.

Referring to FIG. 13, the second detection sensor 143 may be arranged spaced apart from an outer surface of the substrate 10 by a distance to detect the temperature and the pressure of the gas injected from the gas nozzle 133. The second detection sensor 143 may provide the controller 151 with the detected temperature and pressure.

The controller 151 may stop the gas supply to a nozzle among the nozzles of the gas nozzle 133 corresponding to detection position information of the second detection sensor 143 based on the temperature and the pressure of the gas detected by the second detection sensor 143 and the detection position information of the second detection sensor 143.

The above-described embodiments of the present invention are intended to illustrate and not to limit the present invention. Various alternatives and equivalents are possible. The invention is not limited by the embodiments described herein. Nor is the invention limited to any specific type of semiconductor device. Additions, subtractions, or modifications which are apparent in view of the present disclosure are intended to fall within the scope of the appended claims.

What is claimed is:

1. An apparatus for planarizing a substrate, the apparatus comprising:
a supporting plate configured to receive the substrate on which a coating layer is formed before a hardening process, the supporting plate having at least one of a function for controlling a temperature of the substrate, a rotation of the substrate and a vibration of the substrate;
an injection mechanism configured to inject a gas having a set temperature and a set pressure to the coating layer on the substrate to horizontally planarize the coating layer;
a controller configured to control a movement, a temperature and a pressure of the injection mechanism, and to control the temperature control function, the rotation control function and the vibration control function of the supporting plate; and
at least one outlet arranged at a wall of a chamber to exhaust byproducts generated in a process.

2. The apparatus of claim 1, wherein the injection mechanism comprises:
a gas nozzle configured to inject the gas having the set temperature and the set pressure to the coating layer; and
a body plate in fluid communication with the gas nozzle to provide the gas nozzle with the gas having the set temperature and the set pressure.

3. The apparatus of claim 2, wherein the body plate has a rectangular first shape having a first length corresponding to a diameter of the substrate, a rectangular second shape having the first length corresponding to a radius of the substrate, or a third shape having a size smaller than a size of the second shape.

4. The apparatus of claim 2, wherein the gas nozzle comprises any one of a protrusion type nozzle including a plurality of protruded nozzles and a slit type nozzle including a plurality of injection holes,
wherein the body plate has a single region connected to the plurality of the nozzles, or a plurality of regions corresponding to the nozzles, respectively,
is wherein the injection mechanism further comprises an injector connected to the body plate to provide the body plate with the gas having the set temperature and the set pressure by the controller,
wherein the injector provides the gas having a same temperature and a same pressure to the body plate, or the gas having different temperatures and different pressures to the body plate through the plurality of the regions to inject the gas having the different temperatures and the different pressures through the nozzles, and
wherein the injector comprises an amplifier configured to control the pressure.

5. The apparatus of claim 4, wherein the injector individually provides the gas having the set temperature and the set pressure to the regions of the body plate, or blocks the flow of the gas to the regions of the body plate,
wherein the controller determines the set temperature and the set pressure of the gas based on at least one of a material of the coating layer, a viscous force and a glass transition temperature of the coating layer, a threshold temperature and a threshold pressure applicable to the gas nozzle and the regions of the substrate, and
wherein the controller controls the injector to inject the gas having the set temperature and the set pressure.

6. The apparatus of claim 2, wherein the gas nozzle comprises a protrusion type nozzle including a plurality of protruded nozzles, and each of the protruded nozzles has independently variable gas injection angles.

7. The apparatus of claim 2, wherein the gas nozzle comprises any one of a protrusion type nozzle including a plurality of protruded nozzles and a slit type nozzle including a plurality of injection holes, and
wherein the nozzles comprise a first group of nozzles and a second group of nozzles, the first group of the nozzles are connected to a first surface of the body plate, the second group of the nozzles are connected to a second surface of the body plate opposite to the first surface, the first group of the nozzles are arranged on a half portion of the first surface in the body plate with respect to a center point of the body plate, the second group of the nozzles are arranged on a half portion of the second surface in the body plate with respect to the center point of the body plate, and the half portion of the first surface in the body plate on which the first group of the nozzles are arranged is symmetrical with the half portion of the second surface in the body plate on which the second group of the nozzles are arranged such that the first group of the nozzles and the second group of the nozzles have inclined angles to be oriented toward a direction opposite to a rotation direction of the substrate.

8. The apparatus of claim 2, wherein the gas nozzle comprises any one of a protrusion type nozzle including a plurality of protruded nozzles and a slit type nozzle including a plurality of injection holes,
wherein the nozzles comprise a first group of nozzles and a second group of nozzles, the first group of the nozzles are connected to a first surface of the body plate, the second group of the nozzles are connected to a second surface of the body plate opposite to the first surface, the first group of the nozzles are arranged on a half portion of the first surface in the body plate with respect to a center point of the body plate, the second group of the nozzles are arranged on a half portion of the second surface in the body plate with respect to the center point of the body plate, the half portion of the first surface in the body plate on which the first group of the nozzles are arranged is symmetrical with the half portion of the second surface in the body plate on which the second group of the nozzles are arranged, and
wherein the first and second groups of the nozzles and have gradually increased inclined angles from the center point to an edge portion in the body plate.

9. The apparatus of claim 2, further comprising at least one first detection sensor arranged on a region fronting the substrate to detect a distance between the first direction sensor and the substrate on the supporting plate, and to provide the controller with a detected distance,
wherein the controller controls an ascending or descending of the body plate, or on/off operations of the gas having the set temperature and the set pressure based on the detected distance transmitted from the first detection sensor.

10. The apparatus of claim 2, further comprising at least one second detection sensor arranged spaced apart from an outer surface of the substrate by a distance to detect the temperature and the pressure of the gas injected from the nozzles of the gas nozzle, and to provide the controller with the detected temperature and pressure,
wherein the controller stops a gas supply to a nozzle among the nozzles of the gas nozzle corresponding to a detection position information of the second detection sensor based on the temperature and the pressure of the gas detected by the second detection sensor and the detection position information of the second detection sensor.

11. A method of planarizing a substrate, the method comprising:
determining injection conditions including a set temperature and a set pressure of a gas applied to the substrate;
preparing the substrate on which a coating layer is formed before a hardening process; and
injecting the gas having the set temperature and the set pressure to the coating layer on the substrate.

12. The method of claim 11, wherein the gas having the set temperature and the set pressure is injected through a gas nozzle, and the injection conditions are determined based on at least one of a material of the coating layer, a viscous force and a glass transition temperature of the coating layer, a threshold temperature and a threshold pressure applicable to the gas nozzle and regions of the substrate.

13. The method of claim 11, wherein injecting the gas having the set temperature and the set pressure comprises injecting the gas by rotating the gas, with changing the injection direction of the gas along one of the first to fourth directions based on a predetermined time, by moving the gas from one end to the other end in the substrate, or by moving the gas along a predetermined path.

14. The method of claim 11, wherein injecting the gas having the set temperature and the set pressure comprises injecting the gas by rotating the substrate, with controlling a temperature of the substrate, or with applying a vibration to the substrate.

15. The method of claim 11, wherein the gas having the set temperature and the set pressure is injected through a gas nozzle including a plurality of nozzles, and
wherein the nozzles inject the gas having a same temperature and a same pressure or different temperatures and different pressures.

16. The method of claim 11, wherein the gas having the set temperature and the set pressure is injected through a gas nozzle including a plurality of nozzles, and the nozzles individually perform providing the gas having the set temperature and the set pressure, or stopping the providing of the gas.

17. The method of claim 11, wherein the gas having the set temperature and the set pressure is injected through a gas nozzle including a plurality of nozzles, and each of the nozzles has independently variable gas injection angles.

18. The method of claim 11, wherein the gas having the set temperature and the set pressure is injected through a gas nozzle including a plurality of nozzles, further comprising after injecting the gas:
detecting a distance between the gas nozzle and the substrate; and
comparing the detected distance to a reference distance to adjust the distance between the gas nozzle and the substrate.

19. The method of claim 11, wherein the gas having the set temperature and the set pressure is injected through a gas nozzle including a plurality of nozzles, further comprising after injecting the gas:
identifying whether or not the gas is detected in regions outside the substrate;
recognizing a nozzle among the nozzles corresponding to a detected region when the gas is detected in the detected region; and
stopping the injecting the gas from the recognized nozzle.

20. An apparatus comprising:
a supporting plate for receiving a semiconductor substrate, the supporting plate being capable of rotating, and vibrating to impart the rotating and vibrating to the substrate for planarizing a coating layer disposed on the substrate; and
an injection mechanism comprising a plurality of nozzles,
wherein the injection mechanism injects a first gas having a first temperature through at least one of the plurality of the nozzles on a first surface of the coating layer, and a second gas having a second temperature through at least another one of the plurality of nozzles on a second surface of the coating layer.
